(19) United States
(12) Patent Application Publication
(10) Pub. No.: US 2023/0268238 A1
(43) Pub. Date: Aug. 24, 2023

(54) TEST STRUCTURE AND MANUFACTURING METHOD THEREOF

(71) Applicant: CHANGXIN MEMORY TECHNOLOGIES, INC., Hefei City, Anhui (CN)

(72) Inventors: Xiangyu WANG, Hefei City, Anhui (CN); Ning LI, Hefei City, Anhui (CN)

(73) Assignee: CHANGXIN MEMORY TECHNOLOGIES, INC., Hefei City, Anhui (CN)

(21) Appl. No.: 17/606,030

(22) PCT Filed: Jun. 15, 2021
(86) PCT No.: PCT/CN2021/100202

§ 371 Date: Oct. 23, 2021

(30) Foreign Application Priority Data
Nov. 6, 2020 (CN) 202011233637.7

(51) Int. Cl. H01L 21/66

(52) U.S. Cl. CPC H01L 22/34

(57) ABSTRACT

A manufacturing method for a test structure includes: providing a substrate, and forming a gate dielectric film and a conductive film being stacked successively on the substrate; patterned etching at least the conductive film to form a plurality of gate structures discretely located on the substrate, the distance between adjacent gate structures in an arrangement direction of the gate structure being less than or equal to 110 nm; forming isolation sidewalls on two opposite sides of the gate structures; and, implanting doping ions into the substrate to form doped regions by taking the gate structures and the isolation sidewalls as masks, the distance between the doping depth of the doped regions and the top surface of the substrate in a direction perpendicular to the surface of the substrate being less than 10 nm.

### CROSS-REFERENCE TO RELATED APPLICATIONS

The present disclosure claims priority to Chinese Patent Application No. 202011233637.7, entitled “TEST STRUCTURE AND MANUFACTURING METHOD THEREOF”, filed to the China National Intellectual Property Administration on Nov. 6, 2020, which is incorporated herein by reference in its entirety.

### TECHNICAL FIELD

The present disclosure relates to, but not limited to, a test structure and a manufacturing method thereof.

### BACKGROUND

Among modern storage process structures, field effect transistors are one of the most common process devices. In the process of preparing field effect transistors, it is necessary to monitor various parameters of the field effect transistors, for example, the resistance of the gate, the resistance of the conductive plug, the electric leakage of the gate dielectric layer, etc.

In the prior art, it is unable to accurately obtain the resistance of lightly doped drain structures (LDD structures).

### SUMMARY

The following is the summary of the subject described in detail herein. This summary is not intended to limit the protection scope defined by the claims.

The embodiments of the present disclosure provide a test structure and a manufacturing method thereof, which are disadvantageous to obtain accurate and effective resistance values of lightly doped drain structures.

An embodiment of the present disclosure provides a manufacturing method for test structure, comprising following steps: providing a substrate, and forming a gate dielectric film and a conductive film which are stacked successively on the substrate; patterned etching at least the conductive film to form a plurality of gate structures discretely located on the substrate, the distance between adjacent gate structures in an arrangement direction of the gate structure being less than or equal to 110 nm; forming isolation sidewalls on two opposite sides of the gate structures; and, implanting doping ions into the substrate to form doped regions by taking the gate structures and the isolation sidewalls as masks, the doping depth of the doped regions in a direction perpendicular to the surface of the substrate being less than 10 nm.

In some embodiments, the process step of forming the gate structures and the isolation sidewalls comprises: patterned etching the conductive film and the gate dielectric film to form the gate structures; forming an isolation film, the isolation film covering sidewalls of the gate structures and the surface of the substrate; and, etching the isolation film covering the surface of the substrate, and taking the remaining isolation film as the isolation sidewalls.

In some embodiments, the process step of forming the gate structures and the isolation sidewalls comprises: patterned etching the conductive film, taking the remaining conductive film and a part of the gate dielectric film between the remaining conductive film and the substrate as the gate structures and taking the other part of the gate dielectric film as a protective layer; forming an isolation film, the isolation film covering sidewalls of the gate structures and the surface of the protective film; and, taking the isolation film covering the sidewalls of the gate structures as the isolation sidewalls, and taking the isolation film covering the surface of the protective layer as an isolation layer.

In some embodiments, after the isolation film is formed, the isolation layer is removed by etching.

In some embodiments, after the isolation film is formed, the isolation layer and the protective layer between the isolation layer and the substrate are removed by etching.

Correspondingly, an embodiment of the present disclosure further provides a test structure, comprising: a substrate and a plurality of gate structures discretely located on the substrate, the distance between adjacent gate structures in an arrangement direction of the gate structures being less than or equal to 110 nm; isolation sidewalls, located on two opposite sides of the gate structures; and, doped regions, located in the substrate on a side of the isolation sidewalls away from the gate structures, the doping depth of the doped regions in a direction perpendicular to the surface of the substrate being less than or equal to 10 nm.

In some embodiments, first recesses and second recesses are formed in the substrate, the second recesses are at the bottoms of the first recesses; and, in the arrangement direction of the gate structures, the top opening width of the first recesses is equal to the distance between adjacent gate structures, and the top opening width of the second recesses is equal to the distance between two isolation sidewalls between adjacent gate structures.

In some embodiments, each of the gate structures comprises a gate and a gate dielectric layer; the test structure further comprises a protective layer located between the isolation sidewalls and the substrate; and, the material for the protective layer is same as the material for the gate dielectric layer.

In some embodiments, the protective layer covers the surface of the substrate between adjacent gate structures, and recesses are formed in the protective layer; and, in the arrangement direction of the gate structures, the top opening width of the recesses is equal to the distance between adjacent gate structures.

In some embodiments, the test structure further comprises: an isolation layer covering the surface of the protective layer and located between two isolation sidewalls between adjacent gate structures, the material for the isolation layer being same as the material for the isolation sidewalls.

In some embodiments, the recesses comprises first recesses and second recesses, the second recesses are at the bottoms of the first recesses; and, in the arrangement direction of the gate structures, the top opening width of the first recesses is equal to the distance between adjacent gate structures, and the top opening width of the second recesses is equal to the distance between two isolation sidewalls between adjacent gate structures.

In some embodiments, recesses are formed in the substrate; the top opening width of the recesses is equal to the distance between two isolation sidewalls between adjacent gate structures; and, sidewall surfaces of the recesses are continuous surfaces.

In the above technical solutions, by setting the distance between adjacent gate structures to be within a preset range, the over-etching depth during the formation of gate structures is defined, the recesses formed by over-etching are prevented from occupying the preset doping positions for the doped regions too much, the doped regions are ensured to have a large actual doping area, and the resistance values of the doped regions having a preset doping area are accurately obtained.

In addition, during the formation of the gate structures, only the conductive film is removed by etching, that is, the gate dielectric film is used to bear over-etching caused by the etching process of the conductive film, so that it is advantageous to reduce the over-etching depth of the substrate or even make the substrate not bear the damage by over-etching, and a larger effective doping region is obtained. In addition, by directly forming the doped regions after the formation of the isolation film, it is advantageous to avoid forming over-etching recesses in the substrate during the etching process of the isolation layer, so that the doped regions are allowed to have a larger effective doping area and smaller or even minimum resistance values of the doped regions are obtained.

In addition, by etching the protective layer exposed by the gate structures and the isolation sidewalls, over-etching recesses having a preset shape and a smaller depth can be formed on the surface of the substrate, so that the situation where the substrate is subjected to secondary etching in practical applications is simulated, that is, the test resistance values of the doped regions are closer to resistance values in practical applications.

Other aspects will become apparent upon reading and understanding the drawings and detailed description.

### BRIEF DESCRIPTION OF THE DRAWINGS

The drawings incorporated into the specification and constituting a part of the specification show the embodiments of the present disclosure, and are used with the description to explain the principles of the embodiments of the present disclosure. Throughout the drawings, like reference numerals denote like elements. The drawings to be described hereinafter are some but not all of the embodiments of the present disclosure. A person of ordinary skill in the art can obtain other drawings according to these drawings without paying any creative effort.

FIGS. 1 to 5 are schematic structure diagrams corresponding to steps in a manufacturing method for test structure;

FIGS. 6 to 8 are schematic structure diagrams corresponding to steps in a manufacturing method for test structure according to an embodiment of the present invention; and

FIGS. 9 to 14 are schematic structure diagrams corresponding to steps in a manufacturing method for test structure according to another embodiment of the present invention.

### DETAILED DESCRIPTION

In order to make the objectives, technical solutions and advantages of the embodiments of the present disclosure clearer, the technical solutions in the embodiments of the present disclosure will be described below clearly and completely with reference to the drawings in the embodiments of the present disclosure. Apparently, the embodiments to be described are some but not all of the embodiments of the present disclosure. All other embodiments obtained on the basis of the embodiments of the present disclosure by those skilled in the art without paying any creative effort shall fall into the protection scope of the present disclosure. It is to be noted that the embodiments of the present disclosure and the features in the embodiments can be arbitrarily combined with each other if not conflicted.

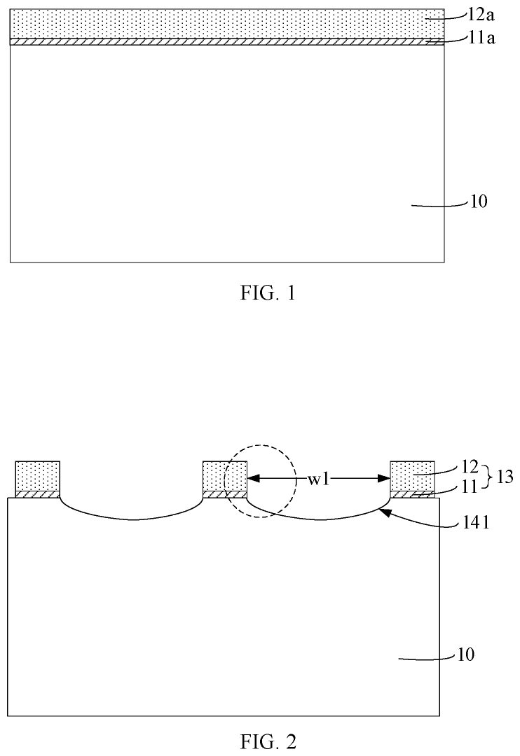

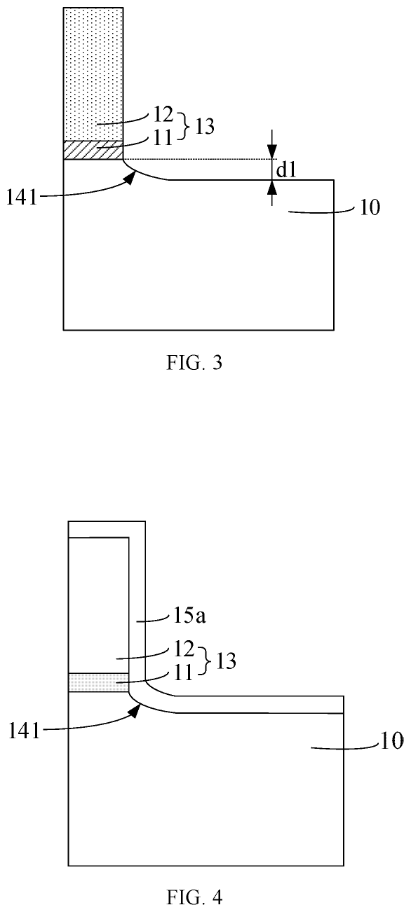

FIGS. 1 to 5 are schematic structure diagrams corresponding steps in a manufacturing method for test structure, where FIG. 3 is a partially schematic diagram of the structure shown in FIG. 2. The manufacturing method for test structure includes the following steps.

Referring to FIG. 1, a substrate 10 is provided, and a gate dielectric film 11a and a conductive film 12a which are stacked successively are formed on the substrate 10.

Referring to FIGS. 2 and 3, gate structures 13 are formed.

The conductive film 12a and the gate dielectric film 11a are etched to form a plurality of gate structures 13 located on the substrate 10. Each of the gate structures 13 comprises a gate 12 and a gate dielectric layer 11, and there is a first width w1 between adjacent gate structures 13. In the process step of forming the gate structures 13, due to the over-etching problem in the etching process, first recesses 141 having a first depth d1 will be formed in the substrate 10.

The size of the first depth d1 is related to the size of the first width w1. In accordance with the etching load effect, the larger the first width w1 is, the larger the first depth d1 is; and, the smaller the first width w1 is, the smaller the first depth d1 is.

Referring to FIG. 4, an isolation film 15a covering the top surfaces and sidewalls of the gate structures 13 and the surface of the substrate 10 is formed.

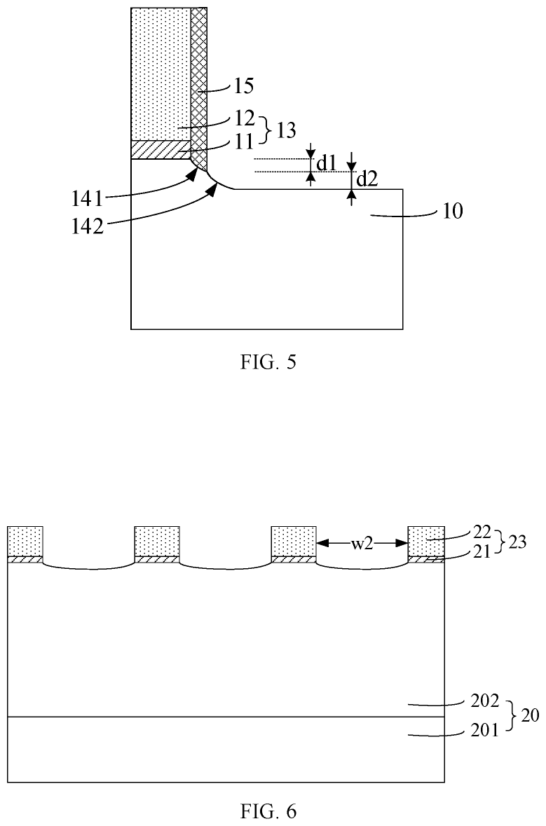

Referring to FIG. 5, isolation sidewalls 15 are formed.

The isolation film 15a covering the top surfaces of the gate structures 13 and the surface of the substrate 10 may be removed by maskless dry etching (referring to FIG. 4), and the remaining isolation film 15a is took as isolation sidewalls 15.

Similarly, in the process step of etching the isolation film 15a covering the surface of the substrate 10, due to the over-etching problem in the etching process, second recesses 142 located at the bottoms of the first recesses 141 will be further formed in the substrate 10.

In accordance with the etching load effect, the size of the second depth d2 is related to the distance between two isolation sidewalls 15 between adjacent gate structures 13. The larger the latter is, the larger the former is. Meanwhile, since the width of the isolation sidewalls 15 in the arrangement direction of the gate structures 13 is usually fixed, the distance between two isolation sidewalls 15 between adjacent gate structures 13 decreases with the decrease of the first width w1. That is, the size of the second depth d2 is mainly related to the first width w1. The larger the first width w1 is, the larger the second depth d2 is.

In the prior art, during testing the resistance of the doped regions, the first width w1 is usually equal to the distance between adjacent gate structures in an actual array region. The effectiveness and accuracy of resistance values obtained by testing is ensured by controlling the testing environment to be same as the practical application environment.

However, as the feature size of the semiconductor structure decreases continuously, the ratio of the depth of the first recesses 141 and second recesses 142 formed by over-etching to the preset doping depth of the doped regions increases gradually, that is, the first recesses 141 and second recesses 142 occupy more of the preset doping area of the doped regions, so that the effective doping area of the doped regions is reduced and the resistance values of the doped regions having a preset doping area cannot be obtained accurately.

For the test structure and manufacturing method thereof according to the embodiment of the present disclosure, the distance between adjacent gate structures is set to be within a preset range. Thus, it is advantageous to reduce the over-etching depth during the formation of gate structures, the recesses formed by over-etching are prevented from occupying the preset doping area of the doped regions too much, the doped regions are ensured to have a large effective doping area, and the resistance values of the doped regions having a preset doping area are obtained more accurately.

FIGS. 6 to 8 are schematic structure diagrams corresponding to steps in a manufacturing method for test structure according to an embodiment of the present disclosure.

Referring to FIG. 6, gate structures 23 are formed.

In this embodiment, after the gate dielectric film and the conductive film are formed, the conductive film and the gate dielectric film are etched successively by a first etching process to expose the surface of the substrate 20. The remaining conductive film is took as gates 22, the remaining gate dielectric film is took as gate dielectric layers 21, and the gates 22 and the gate dielectric layers 21 form the gate structures 23. There is a second width w2 between adjacent gate structures 23. The second width w2 is less than or equal to 110 nm, for example, 90 nm, 80 nm or 70 nm.

The substrate 20 comprises a base 201 and a well region 202. The type of doping ions for the well region 202 is different from the type of doping ions for the base 201, and the concentration of doping ions for the well region 202 is greater than the concentration of doping ions for the base 201. The material for the gate dielectric film comprises silicon dioxide, and the material for the conductive film comprises metal, doped polycrystalline silicon, etc.

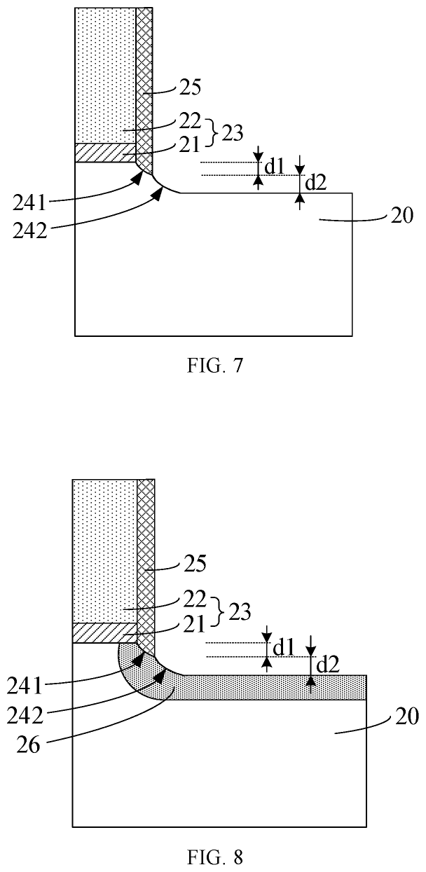

Referring to FIG. 7, isolation sidewalls 25 are formed.

In this embodiment, after the gate structures 23 are formed, an isolation film covering the top surfaces and sidewalls of the gate structures 23 and the surface of the substrate 20 is formed; and, after the isolation film is formed, the isolation film covering the top surfaces of the gate structures 23 and the surface of the substrate 20 is etched by a second etching process, and the remaining isolation film is took as isolation sidewalls 25.

It is to be noted, due to the over-etching problem in the etching process, first recesses 241 located in the substrate 20 will be formed during the first etching process for forming the gate structures 23, and the top opening width of the first recesses 241 is equal to the distance between adjacent gate structures 23. The subsequently formed isolation film will cover the sidewalls and bottom surfaces of the first recesses 241, and the isolation sidewalls 25 in contact with the substrate 20 will be partially located in the substrate 20.

In this embodiment, the isolation sidewalls 25 are used for protecting the gate structures 23 from etching damage caused by the etching process and preventing from doping ions from being implanted into the gate dielectric layers 21 or gates 22 during the doping process, so that the gate structures 23 are ensured to have preset performances.

The material for the isolation sidewalls 25 comprises silicon nitride in order to better support the gate structures 23.

In the process step of etching the isolation film covering the surface of the substrate 20, second recesses 242 at the bottoms of the first recesses 241 will be also formed during the second etching process. Since the gate structures 23 and the isolation sidewalls 25 are took as masks during the second etching process, the top opening width of the second recesses 242 is equal to the distance between two isolation sidewalls 25 between adjacent gate structures 23.

In this embodiment, by defining the size of the second width w2, the first depth d1 of the first recesses 241 and the second depth d2 can be defined within a certain range, and the sum of the first depth d1 and the second depth d2 can be defined within a certain range, thereby ensuring that the doped regions have a larger effective doping area.

Referring to FIG. 8, doped regions 26 are formed.

After the isolation sidewalls 25 are formed, doping ions are implanted into the substrate 20 to form doped regions 26 by taking the gate structures 23 and the isolation sidewalls 25 as masks.

In this embodiment, in a direction perpendicular to the surface of the substrate 20, the orthographic projections of the gate structures 23 are overlapped with the orthographic projections of the doped regions, and at least some of the overlaps are located between the isolation sidewalls 25 and the gate structures 23. It is to be noted that, since the isolation sidewalls 25 can play a shielding role to a certain extent during the ion implantation process, when some isolation sidewalls 25 extend into the substrate 20, the doping ions may not be effectively implanted into some regions between the isolation sidewalls 25 and the gate structures 23. At this time, the doping ions in these regions can only be diffused from other regions.

In this embodiment, the doping depth of the doped regions 26 is less than or equal to 10 nm, for example, 9 nm, 8 nm or 7 nm. The doping depth refers to the maximum implantation depth of the doping ions. When the second width w2 is less than or equal to 110 nm, the doped regions 26 having a doping depth less than or equal to 10 nm have a larger effective doping area, that is, the ratio of the sum of the depth of the first recesses 241 and the depth of the second recesses 242 to the doping depth is smaller. By testing the resistance of the doped regions 26 in the effective doping area, the resistance values of the doped regions having a preset doping area can be obtained accurately.

In this embodiment, by setting the distance between adjacent gate structures to be within a preset range and etching the depth of the first recesses and the second recesses, the recesses formed by over-etching are prevented from occupying the preset doping positions for the doped regions too much, the doped regions are ensured to have a large actual doping area, and the resistance values of the doped regions having a preset doping area are obtained accurately.

Another embodiment of the present disclosure further provides a manufacturing method for test structure. Unlike the previous embodiment, in this embodiment, the gate structures are defined by etching only the conductive film. The detailed description will be given with reference to FIGS. 9-14. FIGS. 9-14 are schematic structure diagrams corresponding to steps in the manufacturing method for test structure according to another embodiment of the present disclosure. For the parts that are same as or corresponding to the previous embodiment, reference is made to the corresponding description of the previous embodiment, and it will not be repeated hereinafter.

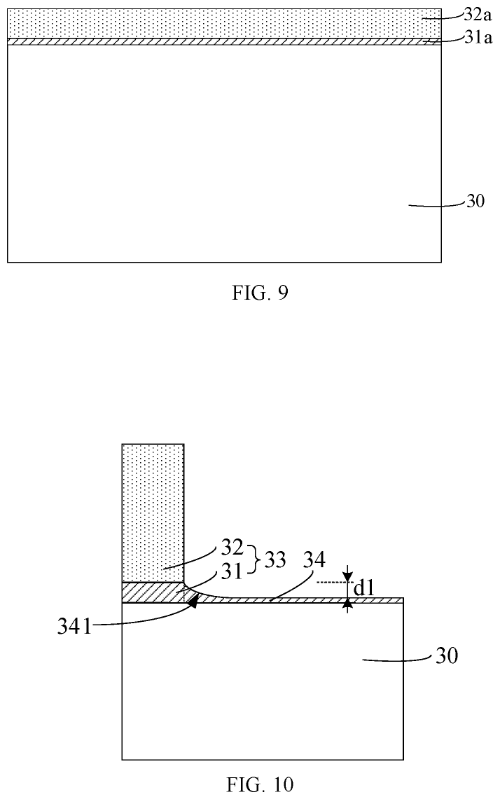

Referring to FIGS. 9 and 10, gate structures 33 are formed.

In this embodiment, after the gate dielectric film 31a and the conductive film 32a are formed on the surface of the substrate 30, the conductive film 32a is patterned and etched to expose the gate dielectric film 31a, the remaining conductive film 32a is took as gates 32, and a part of the gate dielectric film 31a between the gates 32 and the substrate 30 is took as gate dielectric layers 31. The gate dielectric layers 31 and the gates 32 form gate structures 33. The other part of the gate dielectric film 31a between adjacent gate dielectric layers 31 is took as a protective layer 34. In the drawings, the gate dielectric layers 31 and the protective layer 34 are illustrated to be separated by dashed lines.

In this embodiment, in the process step of forming the gate structures 33, the first recesses 341 formed by over-etching are completely located in the protective layer 34, that is, the lowest points of the first recesses 341 are higher than the top surface of the substrate 30 and the first recesses 341 does not expose the surface of the substrate 30; and, the top opening width of the first recesses 341 is equal to the distance between adjacent gate structures 33. In other embodiments, the lowest points of the first recesses are located in the top surfaces of the substrate, or the lowest points of the first recesses are located in the substrate, that is, the bottoms of the first recesses are located in the substrate.

During the testing process, the first width w1 can be adjusted according to the thickness of the protective layer 34 so that the first recesses 341 are completely located in the protective layer 34, thereby avoiding the etching damage to the substrate 30 caused by the over-etching problem in the subsequent etching process and ensuring that the doped regions have the largest effective doping area. That is, the minimum resistance values of the doped regions can be obtained.

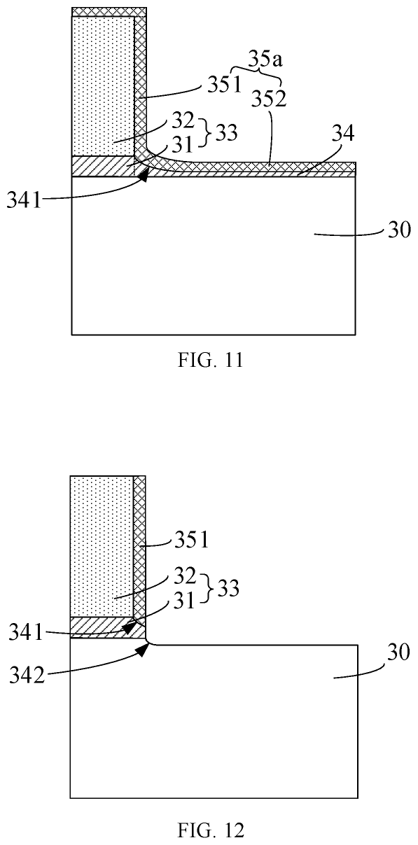

Referring to FIG. 11, isolation sidewalls 351 are formed.

In this embodiment, after the conductive film 32a (referring to FIG. 9) is etched, an isolation film 35a is formed. The isolation film 35a covers the top surfaces and sidewalls of the gate structures 33 and the surface of the protective layer 34. The isolation film 35a covering the sidewalls of the gate structures 33 is took as isolation sidewalls 351, and the isolation film 35a covering the surface of the protective layer 34 is took as an isolation layer 352.

Since the gate dielectric film took as the protective layer 34 is not completely removed in the process of forming the gate structures 33, at least part of the protective layer 34 is located between the isolation sidewalls 351 and the substrate 30 after the isolation film 35a is formed.

In one embodiment, after the isolation film is formed, that is, when the isolation layer is reserved, doping ions are implanted into the substrate to form doped regions. Thus, it is advantageous to avoid the formation of over-etched recesses in the substrate in the etching process of the isolation layer, it is ensured that the doped regions have the largest effective doping area, and the minimum resistance values of the doped regions are obtained. Meanwhile, due to the presence of the isolation layer, the substrate can also be protected from secondary etching.

Referring to FIG. 12, the isolation layer 352 (referring to FIG. 11) and the protective layer 34 between the isolation layer 352 and the substrate 30 are removed by etching.

In this embodiment, second recesses 342 are formed in the substrate 30 during the etching process. The top opening width of the second recesses 342 is equal to the distance between two isolation sidewalls 351 between adjacent gate structures 33, and the sidewall surfaces of the second recesses 342 are continuous surfaces.

In other embodiments, the first recesses are partially located in the substrate, and the second recesses formed subsequently are located at the bottoms of the first recesses. At this time, the recesses in the substrate consist of the second recesses and a part of the first recesses, and the sidewalls of the recesses in the substrate are spliced surfaces.

Since the gate structures usually expose the surface of the substrate in an actual array region, the etching agent may result in secondary etching on the substrate during the etching process for other films. In other words, during the actual operation of field effect transistors, the substrate of the actual array region is usually etched by mistake to a certain extent, so that the effective doping area of the doped regions is smaller than the preset doping area. Meanwhile, since there may not exist the etching process for other films in this embodiment and the distance between adjacent gate structures 33 is defined, the secondary etching has less influence on the substrate than the actual array region. Therefore, by directly forming the second recesses 342 in the substrate 30 by the etching process, the situation where the substrate of the actual array region is subjected to secondary etching can be simulated to a certain extent, so that the resistance values of the doped regions obtained by the test structure are closer to resistance values in practical applications.

In this embodiment, the isolation layer 352 and the protective layer 34 are continuously etched by a same etching process. In other embodiments, the isolation layer and the protective layer can be etched separately by two etching processes. Since the depth of the recesses formed by over-etching is related to factors such as etching selectivity, etching time and top opening width, compared with continuously etching the isolation layer and the protective layer, by separately etching the protective layer, the required etching time is shorter, the required etching solution is less, and the depth of the recessed formed by over-etching is smaller. Thus, the situation where the substrate is etched by mistaken by a small amount of the etching agent during the machining process of the actual array region can be simulated to a certain extent, and a more accurate effective doping area and more accurate resistance values can be obtained.

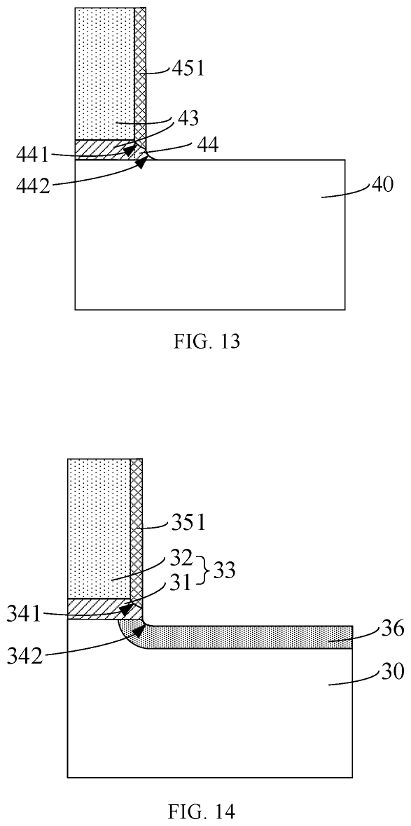

In other embodiments, when there are process steps that may lead to secondary etching in the manufacturing process of the test structure or a simulation test of secondary etching is required, it is also possible to etch only the isolation layer. Referring to FIG. 13, only the isolation layer is etched to form second recesses 442 that expose the surface of the substrate 40, so that the substrate 40 can be subjected to secondary etching from an addition etching agent, thereby simulating the actual situation of the doped regions of the actual array region.

The second recesses 442 are located at the bottoms of the first recesses 441. The top opening width of the first recesses 441 is equal to the distance between adjacent gate structures 43, and the top opening width of the second recesses 442 is equal to the distance between two isolation sidewalls 451 between adjacent gate structures 43. The sidewall surfaces of the recesses consisting of the first recesses 441 and the second recesses 442 are spliced surfaces.

Referring to FIG. 14, after the second etching process, doping ions are implanted into the substrate 30 to form doped regions 36 by taking the gate structures 33 and the isolation sidewalls 351 as masks.

In this embodiment, after the doped regions 36 are formed, other doped regions are further formed at two ends of the doped regions 36 in the extension direction. The type of the doping ions for the other doped regions is different from the type of the doping ions for the doped regions 36, and the concentration of the doping ions for the other doped regions is greater than the concentration of the doping ions for the doped regions 36. The doped regions 36 are took as LDD structures, and the other doped regions are took as source-drain regions.

In this embodiment, only the conductive film is removed by etching in the process of forming the gate structures. Thus, the gate dielectric film can be used to bear part of the over-etching damage, the formation of deep over-etched recesses in the substrate is avoided, and the accuracy and effectiveness of resistance values of the doped regions obtained by testing is ensured.

Those skilled in the art will readily think of other embodiments of the present disclosure by considering the specification and practicing the disclosure. The present disclosure is intended to encompass any variations, uses, or adaptive changes of the present disclosure. These variations, uses, or adaptive changes follow the general principles of the present disclosure and include common knowledge or conventional technical means in the technical field that are not disclosed in the present disclosure. The specification and the embodiments are just exemplary, and the true scope and spirit of the present disclosure are defined by the following claims.

It should be understood that the present disclosure is not limited to the precise structures that have been described above and shown in the drawings, and various modifications and changes may be made without departing from its scope. The scope of the present disclosure is defined only by the appended claims.

### INDUSTRIAL APPLICABILITY

For the test structure and manufacturing method thereof according to the present disclosure, the distance between adjacent gate structures is set to be within a preset range. Thus, it is advantageous to reduce the over-etching depth during the formation of gate structures, the recesses formed by over-etching are prevented from occupying the preset doping area of the doped regions too much, the doped regions are ensured to have a large effective doping area, and the resistance values of the doped regions having a preset doping area are obtained more accurately.

What is claimed is:

1. A manufacturing method for test structure, comprising:
providing a substrate, and forming a gate dielectric film and a conductive film being stacked successively on the substrate;
patterned etching at least the conductive film to form a plurality of gate structures discretely located on the substrate, a distance between adjacent gate structures in an arrangement direction of the gate structures being less than or equal to 110 nm;
forming isolation sidewalls on two opposite sides of the gate structures; and
implanting doping ions into the substrate to form doped regions by taking the gate structures and the isolation sidewalls as masks, a doping depth of the doped regions in a direction perpendicular to a surface of the substrate being less than or equal to 10 nm.

2. The manufacturing method for test structure according to claim 1, wherein the process step of forming the gate structures and the isolation sidewalls comprises:
patterned etching the conductive film and the gate dielectric film to form the gate structures;
forming an isolation film, the isolation film covering sidewalls of the gate structures and the surface of the substrate; and,
etching the isolation film covering the surface of the substrate, and taking the remaining isolation film as the isolation sidewalls.

3. The manufacturing method for test structure according to claim 1, wherein the process step of forming the gate structures and the isolation sidewalls comprises:
patterned etching the conductive film, taking the remaining conductive film and a part of the gate dielectric film between the remaining conductive film and the substrate as the gate structures, and taking the other part of the gate dielectric film as a protective layer;
forming an isolation film, the isolation film covering sidewalls of the gate structures and a surface of the protective film; and, taking the isolation film covering the sidewalls of the gate structures as the isolation sidewalls, and taking the isolation film covering the surface of the protective layer as an isolation layer.

4. The manufacturing method for test structure according to claim 3, wherein, after the isolation film is formed, the isolation layer is removed by etching.

5. The manufacturing method for test structure according to claim 3, wherein, after the isolation film is formed, the isolation layer and the protective layer between the isolation layer and the substrate are removed by etching.

6. A test structure, comprising:
a substrate and a plurality of gate structures discretely located on the substrate, a distance between adjacent gate structures in an arrangement direction of the gate structures being less than or equal to 110 nm;
isolation sidewalls, located on two opposite sides of the gate structures; and
doped regions, located in the substrate on a side of the isolation sidewalls away from the gate structures, a doping depth of the doped regions in a direction perpendicular to the surface of the substrate being less than or equal to 10 nm.

7. The test structure according to claim 6, wherein first recesses and second recesses are formed in the substrate, the second recesses are at bottoms of the first recesses; and, in the arrangement direction of the gate structures, a top opening width of the first recesses is equal to the distance between adjacent gate structures, and a top opening width of the second recesses is equal to a distance between two isolation sidewalls between adjacent gate structures.

8. The test structure according to claim 6, wherein each of the gate structures comprises a gate and a gate dielectric layer; the test structure further comprises a protective layer located between the isolation sidewalls and the substrate; and, the material for the protective layer is same as the material for the gate dielectric layer.

9. The test structure according to claim 8, wherein the protective layer covers a surface of the substrate between adjacent gate structures, and recesses are formed in the protective layer; and, in the arrangement direction of the gate structures, a top opening width of the recesses is equal to the distance between adjacent gate structures.

10. The test structure according to claim 9, further comprising: an isolation layer covering a surface of the protective layer and located between two isolation sidewalls between adjacent gate structures, the material for the isolation layer being same as the material for the isolation sidewalls.

11. The test structure according to claim 9, wherein the recesses comprises first recesses and second recesses, the second recesses are at the bottoms of the first recesses; and, in the arrangement direction of the gate structures, a top opening width of the first recesses is equal to the distance between adjacent gate structures, and a top opening width of the second recesses is equal to a distance between two isolation sidewalls between adjacent gate structures.

12. The test structure according to claim 8, wherein recesses are formed in the substrate; a top opening width of the recesses is equal to a distance between two isolation sidewalls between adjacent gate structures; and, sidewall surfaces of the recesses are continuous surfaces.
